(19) United States
(12) Patent Application Publication
(10) Pub. No.: US 2026/0150228 A1
(43) Pub. Date: May 28, 2026

(54) CENTRIFUGAL HEAT DISSIPATION FAN

(71) Applicant: Acer Incorporated, New Taipei City (TW)

(72) Inventors: Yu-Ming Lin, New Taipei City (TW); Mao-Neng Liao, New Taipei City (TW); Cheng-Wen Hsieh, New Taipei City (TW); Kuang-Hua Lin, New Taipei City (TW); Wei-Chin Chen, New Taipei City (TW); Kuan-Lin Chen, New Taipei City (TW); Tsung-Ting Chen, New Taipei City (TW)

(73) Assignee: Acer Incorporated, New Taipei City (TW)

(21) Appl. No.: 19/392,133

(22) Filed: Nov. 18, 2025

(30) Foreign Application Priority Data
Nov. 27, 2024 (TW) 113145762

(51) Int. Cl. H05K 7/20; F04D 17/08; F04D 29/42; G06F 1/20

(52) U.S. Cl. CPC H05K 7/20172; F04D 17/08; F04D 29/4226; G06F 1/203

(57) ABSTRACT

A centrifugal heat dissipation fan suited for a laptop computer is provided. The centrifugal heat dissipation fan includes a housing, a hub rotating disposed in the housing, a plurality of blades disposed at side of and surrounding the hub, and a mute ring connecting the blades and located at ends of the blades opposite to the hub. The blades and the hub are rotated in a first direction. The mute ring has a plurality of recesses, and a contour of each of the recesses is tapered toward a second direction, wherein the second and the first directions are opposite directions. An airflow passes by the mute ring and enters the recess. After the airflow being gathered together because of the tapered contour, the airflow is squeezed out of the recess and flows toward the housing.

### CROSS-REFERENCE TO RELATED APPLICATION

This application claims the priority benefit of Taiwan application serial no. 113145762, filed on Nov. 27, 2024. The entirety of each of the above-mentioned patent applications is hereby incorporated by reference herein and made a part of this specification.

### BACKGROUND

### Technical Field

The disclosure relates to a heat dissipation fan, and in particular to a centrifugal heat dissipation fan.

### Description of Related Art

The current electronics industry is developing rapidly. As the performance of electronic components continues to improve, the faster the computing speed, the greater the heat generated. Therefore, portable electronic devices, such as laptop computers, need to use centrifugal heat dissipation fans to discharge the air from the portable electronic device to reduce the internal temperature of the device. Furthermore, in order to comply with the current trend of devices that are thin, compact and high-performance, the centrifugal heat dissipation fan in portable electronic devices often faces insufficient configuration space.

For the centrifugal heat dissipation fan, its performance largely depends on the area of the blades. A larger fan blade area means that it can capture more air and generate a larger air flow. However, as the aforementioned configuration space is insufficient, when the space that the fan housing can provide for the blades is limited, the designer may increase the area of the blades as much as possible. As a result, the distance between the blades and the inner wall of the housing will become smaller and smaller.

But this also means that the motor, the hub and the blades need to be more stable during operation, otherwise the blades will easily deflect and hit the housing. On the contrary, during design, due to the above-mentioned stability considerations, the possibility of continued expansion of the blades area is limited.

### SUMMARY

The present application provides a centrifugal heat dissipation fan, which can provide airflow during operation so that the blades can maintain stability relative to the housing.

The centrifugal heat dissipation fan of the present application is suited for a laptop computer. The centrifugal heat dissipation fan includes a housing, a hub, a plurality of blades, and a mute ring. The hub is rotatably disposed in the housing. The blades surround the hub to rotate with the hub in a first direction. The mute ring is connected to the blades and is located at ends of the blades away from the hub. The mute ring has a plurality of recesses. A contour of each of the recesses is tapered toward a second direction, wherein the second direction is opposite to the first direction. After the airflow passes by the mute ring and enters the recess, the airflow being gathered together because of the tapered contour, the airflow is squeezed out of the recess and flows toward the housing.

Based on above, the centrifugal heat dissipation fan responds to the shrinking trend of the internal space of the laptop computer, and its mute ring is set with a plurality of recesses. Each recess has a tapered contour and is tapered along the second direction, wherein the second direction is opposite to the first direction of rotation of the blades. In this way, when the blades rotate in the first direction, the airflow on the mute ring flows in the second direction, causing the airflow to flow into the recesses. Due to the tapered contour, the airflow is gathered and squeezed out of the recess, thereby changing the airflow on the mute ring from the second direction to the normal direction of the top surface of the mute ring, which is the direction of the top surface of the mute ring. The airflow ejected from the mute ring is facing the housing, so it is equivalent to the airflow from the blades toward the housing when the blades are rotating.

Accordingly, when these airflows toward the housing continue to occur as the blades rotate, it is equivalent to forming an air wall or airflow barrier between the blades and the housing to maintain a gap between the blades and the housing. In this way, the rotating blades can achieve a dynamic balance relative to the housing, and may not hit the housing due to deflection.

### BRIEF DESCRIPTION OF THE DRAWINGS

FIG. 1 is a schematic diagram of a laptop computer according to an embodiment of the present application.

FIG. 2 is an exploded diagram of the centrifugal heat dissipation fan.

FIG. 3 is an enlarged schematic diagram of the centrifugal heat dissipation fan of FIG. 2 in part B.

FIG. 4 illustrates a partial side view of the centrifugal heat dissipation fan in a simple diagram.

FIG. 5 illustrates a partial enlarged view of the centrifugal heat dissipation fan of another embodiment.

### DESCRIPTION OF THE EMBODIMENTS

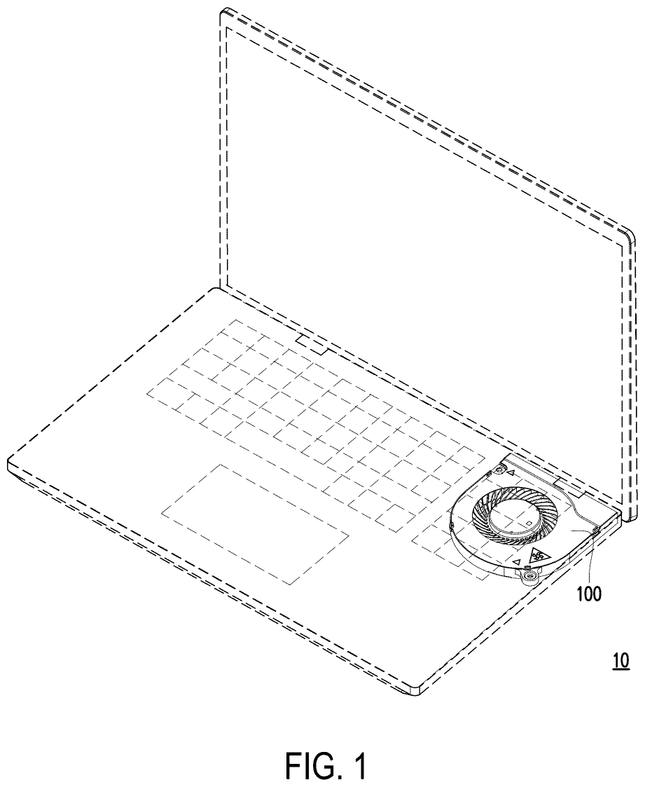

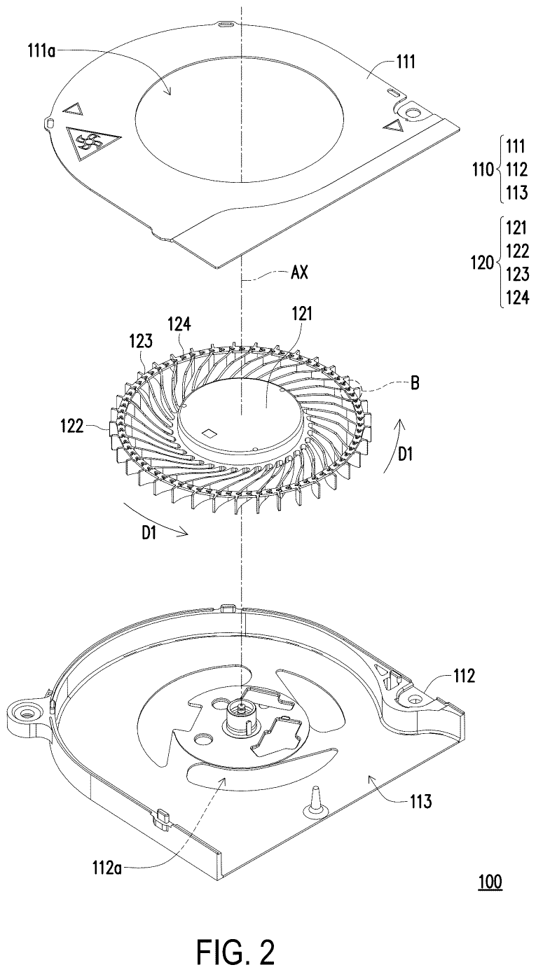

FIG. 1 is a schematic diagram of a laptop computer according to an embodiment of the present application. FIG. 2 is an exploded diagram of the centrifugal heat dissipation fan. Referring to FIG. 1 and FIG. 2 at the same time, in the embodiment, the centrifugal heat dissipation fan 100 is suited for a laptop computer 10 to dissipate heat from a heat source (such as a CPU or GPU) within the laptop computer 10 to expel the heat out of the laptop computer 10. As shown in FIG. 2, the centrifugal heat dissipation fan 100 includes a housing 110 and a blade wheel 120, wherein the blade wheel 120 is connected to a motor (not shown) to rotate along a rotation axis AX in the housing 110.

In the embodiment, the housing 110 includes a base 112 and a top plate 111, wherein the top plate 111 has an air inlet 111a and the base 112 has an air inlet 112a. And after the base 112 and the top plate 111 are combined with each other, an air outlet 113 is further formed. Therefore, when the centrifugal heat dissipation fan 100 is operating, it may generate airflow that is sucked into the housing 110 from the air inlets 111a, 112a, and then discharged from the housing 110 through the air outlet 113.

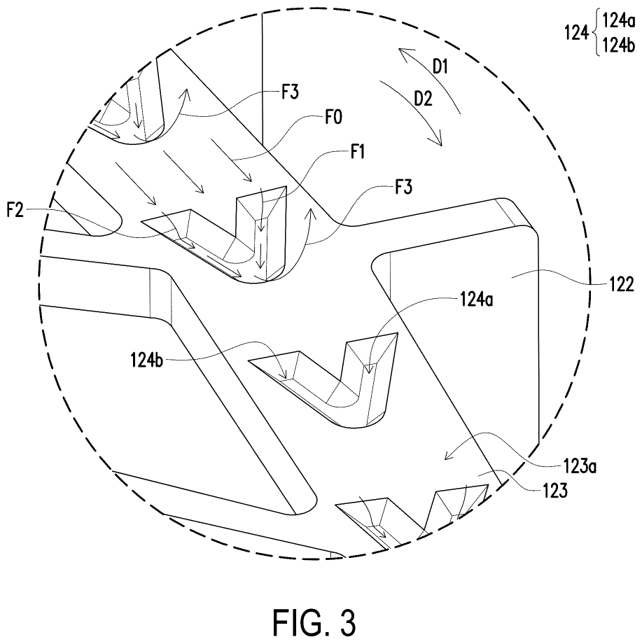

FIG. 3 is an enlarged schematic diagram of the centrifugal heat dissipation fan of FIG. 2 in part B. Referring to FIG. 2 and FIG. 3 at the same time, the blade wheel 120 of the embodiment includes a hub 121, a plurality of blades 122, and a mute ring 123. The hub 121 is rotatably disposed in the housing 110, which is, for example, connected to the aforementioned motor to rotate along the rotation axis AX. The blades 122 are arranged around the hub 121 to rotate in a first direction D1 with the hub 121. The mute ring 123 is connected to the blades 122 and is located at ends of the blades 122 opposite to the hub 121. Here, the mute ring 123 is used to reduce the operating noise of the centrifugal heat dissipation fan 100 and increase the structural strength of the blades 122. This part is already known in the prior art and will not be described again.

Importantly, the mute ring 123 of the embodiment is also provided with a plurality of recesses 124, as shown in FIG. 3. The contour of each recess 124 is tapered along a second direction D2, wherein the second direction D2 is opposite to the first direction D1. In this way, when the centrifugal heat dissipation fan 100 rotates, that is, when the blades 122 rotate along the first direction D1, an airflow along the second direction D2 can be generated. The airflow passing through the mute ring 123 will enter the recess 124, gather at one place due to the tapered contour, and be squeezed out of the recess and blown toward the housing 110. As shown in FIG. 3, the recess 124 of the embodiment has a first flow channel 124a and a second flow channel 124b, and they intersect at one point along the second direction D2, so that the recess 124 of the embodiment has an arrow contour.

Accordingly, when the blades 122 rotate along the first direction D1 and the airflow F0 on the surface of the mute ring 123 (top surface 123a) travels to the recess 124, it will be divided into the air flow F1 along the first flow channel 124a and the air flow F2 along the second flow channel 124b. Until the two meets at one point, they are squeezed out from the recess 124 to form air flow F3.

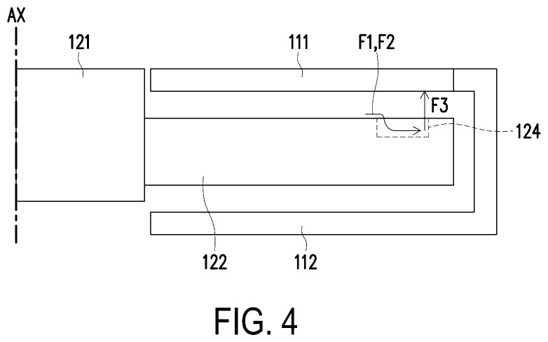

FIG. 4 illustrates a partial side view of the centrifugal heat dissipation fan in a simple diagram. Referring to FIG. 2 and FIG. 3 first, the mute ring 123 is located on the upper edge of the blades 122 so that the recesses 124 face the top plate 111, thereby allowing the airflow to be squeezed out of the recess 124 and then blown towards the top plate 111. Referring to FIG. 3 and FIG. 4, in details, the top surface 123a of the mute ring 123 is flat, and faces the top plate 111 of the housing 110 parallel to each other. The depth direction of the recess 124 is the normal direction of the aforementioned plane (the top surface 123a). Accordingly, when the airflow F3 is squeezed out from the recess 124, it will be blown forward to the top plate 111.

In this way, for the blade wheel 120 as a whole, the recesses 124 on the mute ring 123 may generate an air ring (wall) or air barrier on the top plate 111. That is to say, when the blades 122 continue to rotate, the blades 122 and the top plate 111 can be effectively isolated by the air wall. Since the recesses 124 are equidistantly distributed, the mute ring 123 can maintain a constant gap with the top plate 111 of the housing 110 by the air flow squeezed out from the recesses. The optimal distance (gap) between the upper edge of the blades 122 and the top plate 111 is maintained at 0.6 mm.

Briefly speaking, the generation of the air wall is equivalent to allowing the rotational motion of the blades 122 to be stabilized by the airflow and no longer deflected. Therefore, on the premise that the recess 124 corresponding to the top plate 111 exists on the upper surface of the mute ring 123, the fan designer can increase the area of the blades 122 as much as possible without any worries. In this way, it helps to increase the airflow of the centrifugal heat dissipation fan 100 and optimize the heat dissipation performance of the centrifugal heat dissipation fan 100.

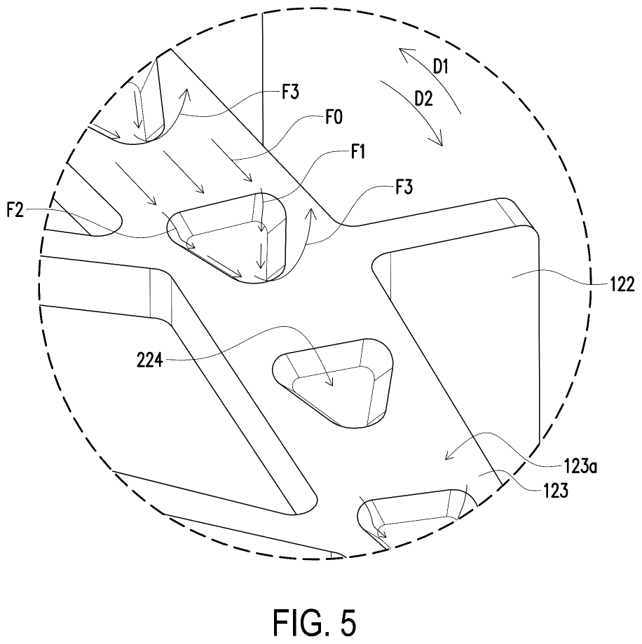

FIG. 5 illustrates a partial enlarged view of the centrifugal heat dissipation fan of another embodiment. Referring to FIG. 5 and comparing to FIG. 3, the difference from the previous embodiment is that the recess 224 of the embodiment has a triangular contour, but what remains unchanged is its tapering feature along the second direction D2. Accordingly, the recess 224 of the embodiment can also be used to generate airflow F3, and allow the airflow F3 to resist the top plate 111 of the housing 110, thereby generating the same air wall as in the previous embodiment.

In summary, in the above-mentioned embodiment of the application, the centrifugal heat dissipation fan is provided with a plurality of recesses on the mute ring in response to the shrinking trend of the internal space of the laptop computer. Each recess has the tapered contour, and is tapered along the second direction, wherein the second direction is opposite to the first direction of the blade rotation. In this way, when the blades rotate in the first direction, the airflow on the mute ring flows in the second direction, causing the airflow to flow into the recess. And due to the tapered contour, the airflow is gathered and squeezed out of the recess, thereby changing the airflow on the mute ring from the second direction to the normal direction of the top surface of the mute ring, that is, the direction of ejecting from the top surface of the mute ring. The airflow ejected from the mute ring is facing the housing, so it is equivalent to the airflow from the blades toward the housing when the blades rotate.

Accordingly, when these airflows toward the housing continue to occur as the blades rotate, it is equivalent to forming an air wall or airflow barrier between the blades and the housing to maintain a gap between the blades and the housing. In this way, the rotating blades can achieve a dynamic balance relative to the housing, and may not hit the housing due to deflection. In contrast, fan designers can maximize the area of the blades without any worries due to the air barrier created by the recessed structural features of the mute ring. This may help increase the airflow of the centrifugal heat dissipation fan, thereby optimizing the heat dissipation performance of the centrifugal heat dissipation fan.

What is claimed is:

1. A centrifugal heat dissipation fan, suited for a laptop computer, the centrifugal heat dissipation fan comprises:
a housing;
a hub, rotatably disposed in the housing;
a plurality of blades, arranged around the hub to rotate in a first direction with the hub; and
a mute ring, connecting to the blades and located at ends of the blades opposite to the hub, the mute ring has a plurality of recesses, and a contour of each of the recesses is tapered toward a second direction, wherein the first direction is opposite to the second direction, after airflow passes by the mute ring and enters the recess, the airflow is gathered together because of the tapered contour and squeezed out of the recess and flows toward the housing.

2. The centrifugal heat dissipation fan according to claim 1, wherein the housing has a base and a top plate, the mute ring is located on the upper edge of the blades, the recesses face the top plate, the airflow is squeezed out of the recess and then blown toward the top plate.

3. The centrifugal heat dissipation fan according to claim 2, wherein the distance between the upper edge of the blades and the top plate is 0.6 mm.

4. The centrifugal heat dissipation fan according to claim 1, wherein the recesses are equidistantly distributed so that the mute ring maintains a gap with the housing through the airflow.

5. The centrifugal heat dissipation fan according to claim 1, wherein the recess has a first flow channel and a second flow channel that intersect at one point along the second direction.

6. The centrifugal heat dissipation fan according to claim 1, wherein the recess has a triangular contour.

7. The centrifugal heat dissipation fan according to claim 1, wherein the recess has an arrow contour.

8. The centrifugal heat dissipation fan according to claim 1, wherein the mute ring has a flat top surface, facing parallel to the top plate of the housing, and a depth direction of the recess is a normal direction of the plane.
